(19) United States
(12) Patent Application Publication
(10) Pub. No.: US 2012/0068251 A1
(43) Pub. Date: Mar. 22, 2012

(54) SEMICONDUCTOR MEMORY DEVICE

(75) Inventors: Masaaki Higuchi, Mie-ken (JP); Junya Fujita, Mie-ken (JP)

(73) Assignee: Kabushiki Kaisha Toshiba, Tokyo (JP)

(21) Appl. No.: 13/004,238

(22) Filed: Jan. 11, 2011

(30) Foreign Application Priority Data
Sep. 22, 2010 (JP) 2010-212846

(51) Int. Cl. H01L 29/792

(52) U.S. Cl. 257/324; 257/E29.309

(57) ABSTRACT

According to one embodiment, a semiconductor memory device includes a multilayer body, a block layer, a charge storage layer, a tunnel layer, and a semiconductor pillar. The multilayer body includes a plurality of insulating films and electrode films alternately stacked. The multilayer body includes a through hole extending in stacking direction of the insulating films and the electrode films. The block layer is provided on an inner surface of the through hole. The charge storage layer is surrounded by the block layer. The tunnel layer is surrounded by the charge storage layer. The semiconductor pillar is surrounded by the tunnel layer. Dielectric constant of a portion of the tunnel layer on a side of the semiconductor pillar is higher than dielectric constant of a portion of the tunnel layer on a side of the charge storage layer.

### CROSS-REFERENCE TO RELATED APPLICATIONS

This application is based upon and claims the benefit of priority from the prior Japanese Patent Application No. 2010-212846, filed on Sep. 22, 2010; the entire contents of which are incorporated herein by reference.

### FIELD

Embodiments described herein relate generally to a semiconductor memory device.

### BACKGROUND

A collectively processed multilayer memory is proposed as a way to increase the capacity and reduce the cost of a semiconductor memory device. In a collectively processed multilayer memory, insulating films and electrode films are alternately stacked on a semiconductor substrate to form a multilayer body. Then, through holes are formed in the multilayer body by lithography. A block layer, a charge storage layer, and a tunnel layer are deposited in this order in the through hole. Furthermore, a silicon pillar is buried in the through hole. Thus, the multilayer memory is manufactured. In such a multilayer memory, a memory transistor is formed at the intersection of the electrode film and the silicon pillar and serves as a memory cell. By applying voltage between the electrode film and the silicon pillar, electric charge is injected from the silicon pillar through the tunnel layer into the charge storage layer to store data.

### BRIEF DESCRIPTION OF THE DRAWINGS

FIG. 1 is a perspective view illustrating a semiconductor memory device according to an embodiment;

FIG. 2 is a sectional view illustrating the semiconductor memory device according to the embodiment;

FIG. 3 is a sectional view illustrating the vicinity of the silicon pillar of the semiconductor memory device according to the embodiment;

FIG. 4 is a graph illustrating the characteristics of a tunnel layer of the semiconductor memory device according to the embodiment;

FIG. 5 is a graph for memory films formed from a silicon oxide film and formed from a silicon nitride film, where the horizontal axis represents the value of R×log(1+T/R), and the vertical axis represents the programming voltage V_{prg}; and

FIG. 6A is a graph illustrating the profile of the dielectric constant, FIG. 6B is a graph illustrating the profile of the electric field intensity for a voltage of 20 V and FIG. 6C is a graph illustrating the profile of the electric field intensity for a maximum electric field of 16 MV/cm.

### DETAILED DESCRIPTION

In general, according to one embodiment, a semiconductor memory device includes a multilayer body, a block layer, a charge storage layer, a tunnel layer, and a semiconductor pillar. The multilayer body includes a plurality of insulating films and electrode films alternately stacked. The multilayer body includes a through hole extending in stacking direction of the insulating films and the electrode films. The block layer is provided on an inner surface of the through hole. The charge storage layer is surrounded by the block layer. The tunnel layer is surrounded by the charge storage layer. The semiconductor pillar is surrounded by the tunnel layer. Dielectric constant of a portion of the tunnel layer on a side of the semiconductor pillar is higher than dielectric constant of a portion of the tunnel layer on a side of the charge storage layer.

An embodiment of the invention will now be described with reference to the drawings.

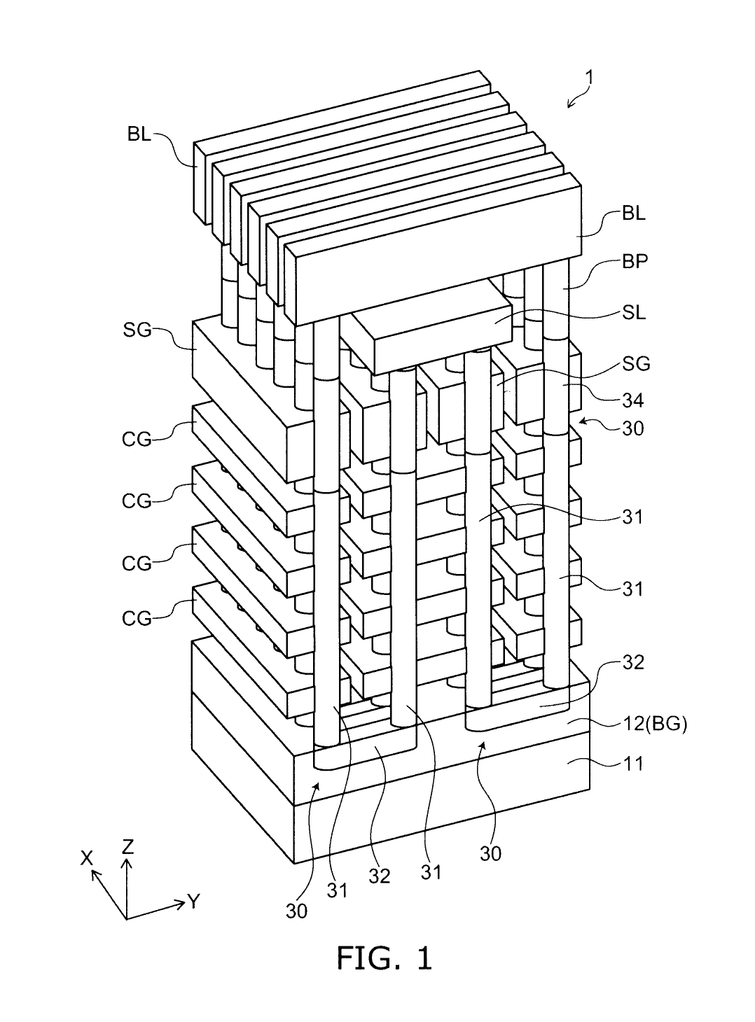

FIG. 1 is a perspective view illustrating a semiconductor memory device according to this embodiment.

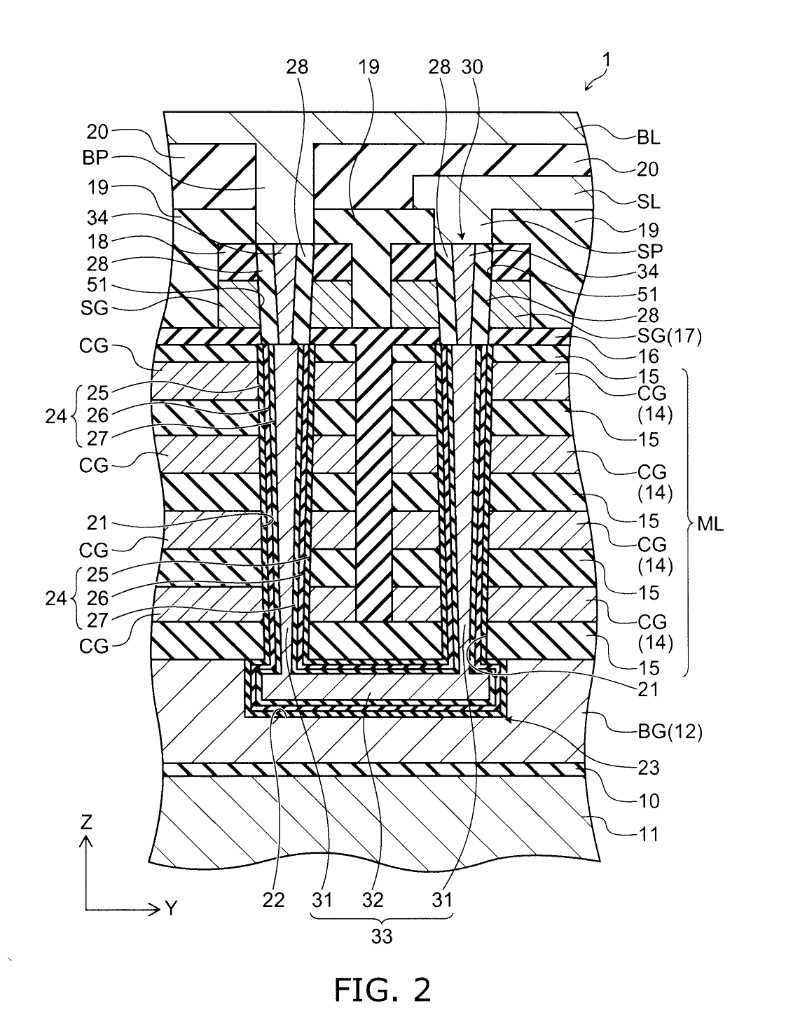

FIG. 2 is a sectional view illustrating the semiconductor memory device according to this embodiment.

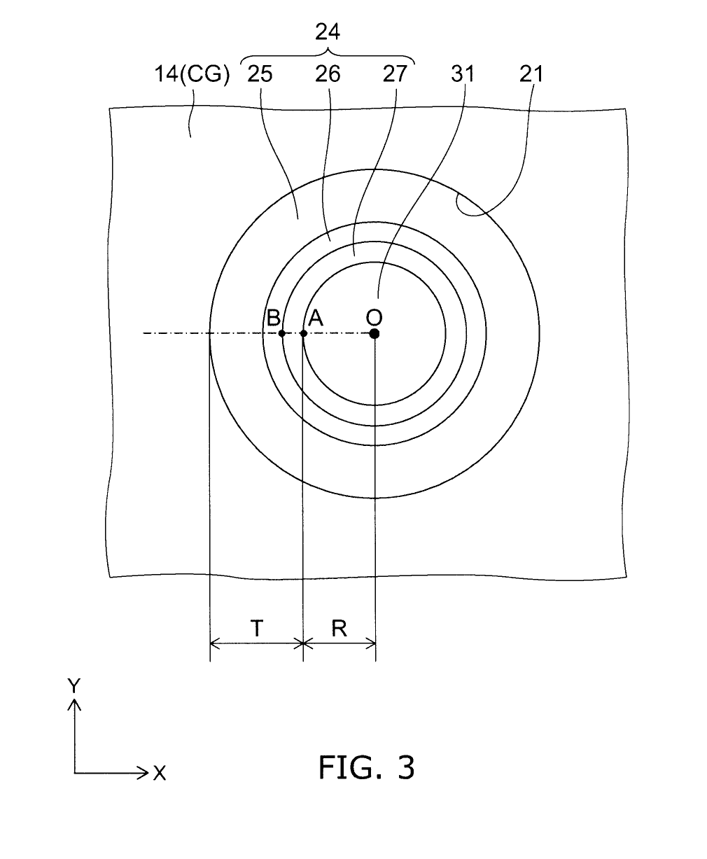

FIG. 3 is a sectional view illustrating the vicinity of the silicon pillar of the semiconductor memory device according to the embodiment.

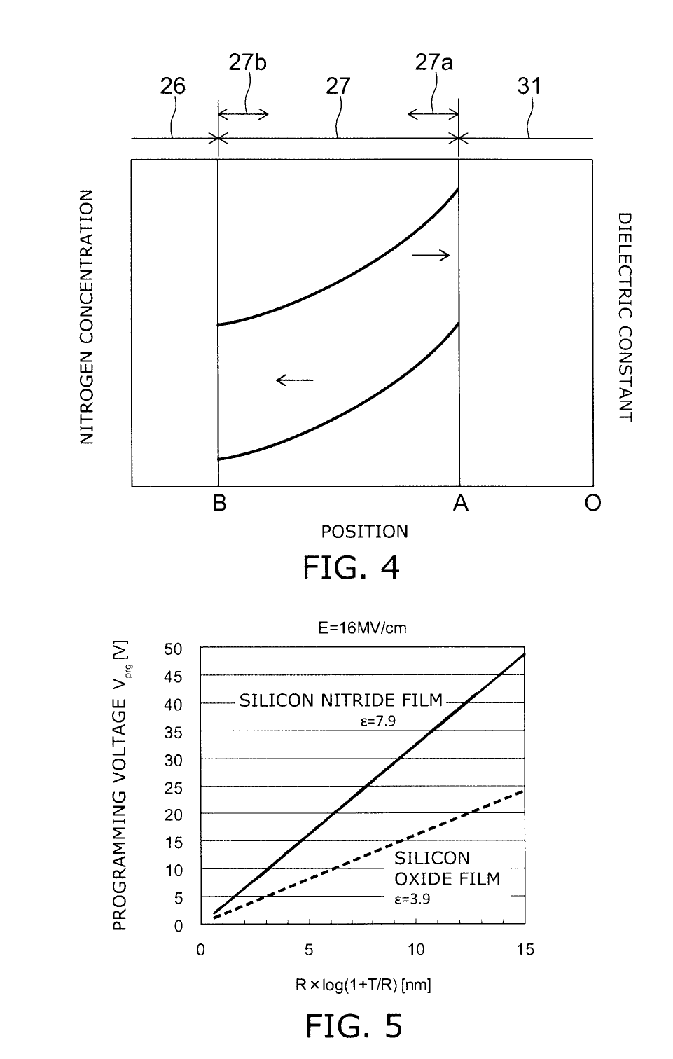

FIG. 4 is a graph illustrating the characteristics of the tunnel layer of the semiconductor memory device according to the embodiment, where the horizontal axis represents distance from the center of the through hole, and the vertical axis represents nitrogen concentration and dielectric constant.

For clarity of illustration, FIG. 1 shows only the conductive portions, and the illustration of the insulating portions is omitted.

The semiconductor memory device according to this embodiment is a multilayer nonvolatile memory device.

As shown in FIGS. 1 and 2, in the semiconductor memory device 1 according to this embodiment, an insulating film 10 is provided on a silicon substrate 11. A conductive film, such as a polysilicon film 12, is formed on the insulating film 10 and serves as a back gate BG. On the back gate BG, a plurality of electrode films 14 and insulating films 15 are alternately stacked to constitute a multilayer body ML.

In the following, for convenience of description, an XYZ orthogonal coordinate system is herein introduced. In this coordinate system, the two directions parallel to the upper surface of the silicon substrate 11 and orthogonal to each other are referred to as X and Y direction, and the direction orthogonal to both the X and Y direction, i.e., the stacking direction of the electrode films 14 and insulating films 15, is referred to as Z direction.

The electrode film 14 is formed from e.g. polysilicon doped with impurity. The electrode film 14 is divided along the Y direction into a plurality of control gate electrodes CG extending in the X direction. As viewed from above in the Z direction, the electrode films 14 in the respective layers are patterned in the same pattern. On the other hand, the insulating film 15 is made of e.g. silicon oxide (SiO₂) and functions as an interlayer insulating film for insulating the electrode films 14 from each other.

On the multilayer body ML, an insulating film 16, an electrode film 17, and an insulating film 18 are formed in this order. The electrode film 17 is made of e.g. polysilicon doped with impurity, and divided along the Y direction into a plurality of select gate electrodes SG extending in the X direction. Two select gate electrodes SG are provided immediately above each uppermost control gate electrode CG.

An insulating film 19 is provided on the insulating film 18. A source line SL extending in the X direction is provided on the insulating film 19. The source line SL is located immediately above every other control gate electrode CG of the uppermost control gate electrodes CG arranged along the Y direction. On the insulating film 19, an insulating film 20 is provided so as to cover the source line SL. A plurality of bit lines BL extending in the Y direction are provided on the insulating film 20. The source line SL and the bit line BL are each formed from a metal film.

In the multilayer body ML, a plurality of through holes 21 extending in the stacking direction (Z direction) of the layers are formed through the multilayer body ML. As viewed in the Z direction, the through hole 21 has e.g. a circular shape. Each through hole 21 penetrates through the control gate electrode CG of each stage, and the lower end of the through hole 21 reaches the back gate BG. The through holes 21 are arranged in a matrix along the X and Y direction. Two through holes 21 arranged in the Y direction are paired. The through holes 21 belonging to the same pair penetrate through the same control gate electrode CG.

In the upper portion of the back gate BG, a communication hole 22 is formed so that the lower end portion of one through hole 21 is allowed to communicate with the lower end portion of another through hole 21 spaced by one row in the Y direction as viewed from the former through hole 21. Thus, one continuous U-shaped hole 23 is formed from a pair of through holes 21 adjacent in the Y direction and the communication hole 22 allowing them to communicate with each other. A plurality of U-shaped holes 23 are formed in the multilayer body ML.

As shown in FIGS. 2 and 3, a memory film 24 is provided on the inner surface of the U-shaped hole 23. In the memory film 24, sequentially from outside, an insulative block layer 25, a charge storage layer 26, and an insulative tunnel layer 27 are stacked. That is, the block layer 25 is provided on the inner surface of the through hole 21, the charge storage layer 26 is surrounded by the block layer 25, and the tunnel layer 27 is surrounded by the charge storage layer 26. The block layer 25 is a layer which passes no substantial current even if a voltage is applied within the driving voltage range of the device 1. The block layer 25 is formed from e.g. silicon oxide. However, the block layer 25 may be formed from silicon oxynitride. The charge storage layer 26 is a layer capable of trapping charge. The charge storage layer 26 is formed from e.g. silicon nitride. The tunnel layer 27 is a layer which is normally insulative, but passes a tunneling current when a prescribed voltage within the driving voltage range of the device 1 is applied. The tunnel layer 27 is formed from e.g. a material containing silicon (Si), oxygen (O), and nitrogen (N), such as nitrogen-containing silicon oxide.

On the tunnel layer 27, a semiconductor material, such as polysilicon, doped with impurity is buried. Thus, a U-shaped silicon member 33 is provided inside the U-shaped hole 23. In the U-shaped silicon member 33, the portion located in the through hole 21 constitutes a silicon pillar 31, and the portion located in the communication hole 22 constitutes a connecting member 32. That is, the silicon pillar 31 is surrounded by the tunnel layer 27. As viewed in the Z direction, the silicon pillar 31, the tunnel layer 27, the charge storage layer 26, and the block layer 25 are arranged concentrically, for instance. The memory film 24 is located between the U-shaped silicon member 33 on one hand and the back gate BG and the control gate electrode CG on the other. Hence, the U-shaped silicon member 33 is insulated from the back gate BG and the control gate electrode CG by the memory film 24.

Furthermore, a plurality of through holes 51 extending in the Z direction are formed in the insulating film 16, the select gate electrode SG, and the insulating film 18. Each through hole 51 is formed immediately above the corresponding through hole 21, and communicates with the through hole 21. A gate insulating film 28 made of e.g. silicon oxynitride is formed on the inner surface of the through hole 51. Furthermore, a silicon pillar 34 made of polysilicon doped with impurity is provided in the space surrounded by the gate insulating film 28. The lower end portion of the silicon pillar 34 is connected to the upper end portion of the silicon pillar 31 formed therebelow. The U-shaped silicon member 33 and a pair of silicon pillars 34 connected to the upper end portion of the U-shaped silicon member 33 constitute a U-shaped pillar 30.

Of a pair of silicon pillars 34 belonging to each U-shaped pillar 30, one silicon pillar is connected to the source line SL through a source plug SP buried in the insulating film 19, and the other silicon pillar is connected to the bit line BL through a bit plug BP buried in the insulating films 19 and 20. Hence, the U-shaped pillar 30 is connected between the bit line BL and the source line SL. The arrangement pitch in the Y direction of the U-shaped pillars 30 is equal to that of the control gate electrodes CG. However, the phase is shifted by half the pitch. Hence, a pair of silicon pillars 31 belonging to each U-shaped pillar 30, i.e., the two silicon pillars 31 connected to each other by the connecting member 32, penetrate through different control gate electrodes CG.

In the device 1, the silicon pillar 31 functions as a channel, and the control gate electrode CG functions as a gate electrode. Thus, a vertical memory transistor is formed at the intersection of the silicon pillar 31 and the control gate electrode CG. Each memory transistor functions as a memory cell by storing electrons in the charge storage layer 26 located between the silicon pillar 31 and the control gate electrode CG. In the multilayer body ML, a plurality of silicon pillars 31 are arranged in a matrix along the X and Y direction. Hence, a plurality of memory transistors are arranged three-dimensionally along the X, Y, and Z direction.

Furthermore, at the intersection of the silicon pillar 34 and the select gate electrode SG, a select transistor is formed with the silicon pillar 34 serving as a channel, the select gate electrode SG as a gate electrode, and the gate insulating film 28 as a gate insulating film. Like the aforementioned memory transistor, this select transistor is also a vertical transistor.

Furthermore, the memory film 24 is interposed between the connecting member 32 and the back gate BG. Hence, a back gate transistor is formed with the connecting member 32 serving as a channel, the back gate BG as a gate electrode, the memory film 24 as a gate insulating film. That is, the back gate BG functions as an electrode for controlling the conduction state of the connecting member 32 by electric field.

As shown in FIGS. 3 and 4, the composition of the tunnel layer 27 is graded in the radial direction of the through hole 21. The positions O, A, and B indicated on the horizontal axis of FIG. 4 represents the positions of the central axis O of the through hole 21, the interface A between the silicon pillar 31 and the tunnel layer 27, and the interface B between the tunnel layer 27 and the charge storage layer 26, respectively, in the radial direction of the through hole 21 shown in FIG. 3. Here, the central axis O of the through hole 21 coincides with the central axis of the silicon pillar 31.

The portion 27a of the tunnel layer 27 on the silicon pillar 31 side has a higher nitrogen concentration than the portion 27b of the tunnel layer 27 on the charge storage layer 26 side. The dielectric constant of silicon oxide increases with the increase of nitrogen concentration. Hence, in the tunnel layer 27, the portion 27a on the silicon pillar 31 side has a higher dielectric constant than the portion 27b on the charge storage layer 26 side. The composition distribution of the tunnel layer 27 is symmetric about the central axis O of the through hole 21 in all directions parallel to the XY plane. Such a tunnel layer 27 can be formed by, for instance, varying the flow rate ratio between the oxidizing gas and the nitridizing gas supplied into the chamber in the ALD (atomic layer deposition) method.

Next, the operation and effect of this embodiment are described.

In the semiconductor memory device 1 according to this embodiment, as viewed in the Z direction, the outer surface of the silicon pillar 31 has a circular shape. The tunnel layer 27, the charge storage layer 26, and the block layer 25 have an annular shape. The surface of the control gate electrode CG constituting the inner surface of the through hole 21 has a circular shape. In response to a voltage applied between the silicon pillar 31 and the control gate electrode CG, an electric field is applied to the tunnel layer 27, the charge storage layer 26, and the block layer 25 nearly uniformly in all directions about the central axis O. Thus, the electric field intensity of various portions of the memory film 24 can be expressed by the following equation (1):

$$E = \frac{k}{2 πɛ r} \qquad ( 1 )$$

where E is the intensity of the electric field applied to various portions of the memory film 24, k (C/cm) is the charge density, r is the distance from the central axis O, ∈ is the dielectric constant, and n is the ratio of the circumference of a circle to its diameter.

From the above equation (1), the electric field intensity E increases as the value of r decreases, i.e., toward the central axis O. Thus, in the memory film 24, the electric field intensity is maximized in the innermost portion, i.e., in the portion of the tunnel layer 27 in contact with the silicon pillar 31. Hence, the electric field concentrates on this portion, and this portion is prone to insulation breakdown.

Thus, in this embodiment, the nitrogen concentration in the portion 27a of the tunnel layer 27 on the silicon pillar 31 side is made higher than the nitrogen concentration in the portion 27b on the charge storage layer 26 side. Hence, the portion 27a has a higher dielectric constant ∈ than the portion 27b. By increasing the dielectric constant ∈, as expressed in the above equation (1), the electric field intensity E can be reduced. That is, the increase of electric field intensity E with the decrease of the distance r from the central axis O can be compensated by increasing the dielectric constant ∈. This relaxes electric field concentration in the tunnel layer 27, and can prevent insulation breakdown. Hence, the semiconductor memory device 1 according to this embodiment has high reliability.

Thus, the semiconductor memory device 1 according to this embodiment is a three-dimensional multilayer memory device, and the memory cell portion has a generally concentric structure. Hence, if the dielectric constant in the tunnel layer 27 is not varied in the thickness direction, the electric field concentrates on the inner periphery portion of the tunnel layer 27, causing reliability degradation. In contrast, in the case of a planar NAND flash memory, an active area is formed in the upper portion of a silicon substrate, a planar gate oxide film is formed on the silicon substrate, and a floating gate electrode and a control gate electrode are provided thereon. Hence, electric field concentration based on the concentric structure does not occur. Thus, the above technique is unnecessary.

Furthermore, for the voltage V applied between the silicon pillar 31 and the control gate electrode CG, the following equation (2) holds:

$$V = \frac{k}{2 π {ɛ}_{0}} \times log ( \frac{b}{a} ) \qquad ( 2 )$$

where ∈₀ is the vacuum dielectric constant, a is the radius of the silicon pillar 31, and b is the value obtained by adding the thickness of the tunnel layer 27 to the radius of the silicon pillar 31.

The above equations (1) and (2) and FIG. 3 yield the following equation (3):

$$V = \frac{ɛ}{{ɛ}_{0}} \times E \times R \times log ( 1 + \frac{T}{R} ) \qquad ( 3 )$$

where, as shown in FIG. 3, R is the radius of the silicon pillar 31, and T is the film thickness of the memory film 24, and assuming that the density k of charge stored in the memory film 24 is fixed in the memory film 24.

From the above equation (3), if the radius R of the silicon pillar 31 and the film thickness T of the memory film 24 are fixed, then by increasing the dielectric constant ∈ of the memory film 24, a higher voltage V can be applied while maintaining the same electric field intensity E. Thus, the voltage required to drive the semiconductor memory device 1, such as the programming voltage V_{prg}, can be increased, and the operating speed of the device 1 can be increased.

In the following, this effect is described specifically.

FIG. 5 is a graph for memory films formed from a silicon oxide film and formed from a silicon nitride film, where the horizontal axis represents the value of R×log(1+T/R), and the vertical axis represents the programming voltage V_{prg}.

The dielectric constant ∈ of silicon oxide is 3.9, and the dielectric constant ∈ of silicon nitride is 7.9. The electric field intensity E is set to 16 MV/cm, which is the breakdown voltage of silicon oxide.

As shown in FIG. 5, the applicable programming voltage V_{prg} can be increased by increasing the dielectric constant ∈ of the memory film 24.

In this embodiment, the dielectric constant of the tunnel layer 27 may monotonically increase in the direction from the inner surface of the through hole 21 to the central axis O. Thus, the increase of the electric field intensity E can be suppressed in the overall tunnel layer 27. For instance, preferably, the dielectric constant of the tunnel layer 27 is inversely proportional to the distance from the central axis O. In this case, from the above equation (1), the electric field intensity E in the tunnel layer 27 can be fixed, and the voltage V can be maximized. Alternatively, in the direction from the inner surface of the through hole 21 to the central axis O, the dielectric constant of the tunnel layer 27 may be fixed in the outer portion of the tunnel layer 27, i.e., in the portion relatively far from the central axis O, and monotonically increase in the inner portion of the tunnel layer 27, i.e., in the portion relatively near to the central axis O. Such a tunnel layer 27 can be formed by, for instance, diffusing nitrogen from the inner side surface of the tunnel layer 27. Thus, in the inner portion of the tunnel layer 27 prone to electric field concentration, the electric field intensity E can be reduced.

Furthermore, in this embodiment, also in the gate insulating film 28, as in the memory film 24, the dielectric constant in the portion on the silicon pillar 34 side is preferably made higher than the dielectric constant in the portion on the select gate electrode SG side. This relaxes electric field concentration in the portion of the gate insulating film 28 in contact with the silicon pillar 34, and enables higher voltage to be applied between the silicon pillar 34 and the select gate electrode SG. Consequently, in data erasing operation, for instance, higher GIDL (gate induced drain leakage) can be obtained, and the erasing speed can be increased. Here, the gate insulating film 28 may be formed from silicon oxynitride with graded nitrogen concentration as described above, but may be a three-layer film like the memory film 24.

Furthermore, in this embodiment, the tunnel layer 27 contains nitrogen. Hence, the tunnel layer 27 is positively charged, and the portion of the silicon pillar 31 surrounded by the insulating film 15 has a higher potential. This reduces the parasitic resistance of the silicon pillar 31 and increases the on-current. Consequently, the time required for reading operation decreases, and high speed operation can be achieved.

In the example of this embodiment described above, the electrode film 14 is formed from polysilicon containing impurity. However, the invention is not limited thereto. The electrode film 14 may be formed from e.g. tantalum nitride, or silicate primarily composed of metal and silicon. In this case, the metal can be nickel or tungsten. Furthermore, in the example described above, the tunnel layer 27 is formed from silicon oxynitride. However, the invention is not limited thereto. The tunnel layer 27 may be formed from hafnium silicon oxide containing silicon, oxygen, and hafnium. In this case, the dielectric constant increases with the increase of the concentration of hafnium.

In the following, a practical example of this embodiment is described.

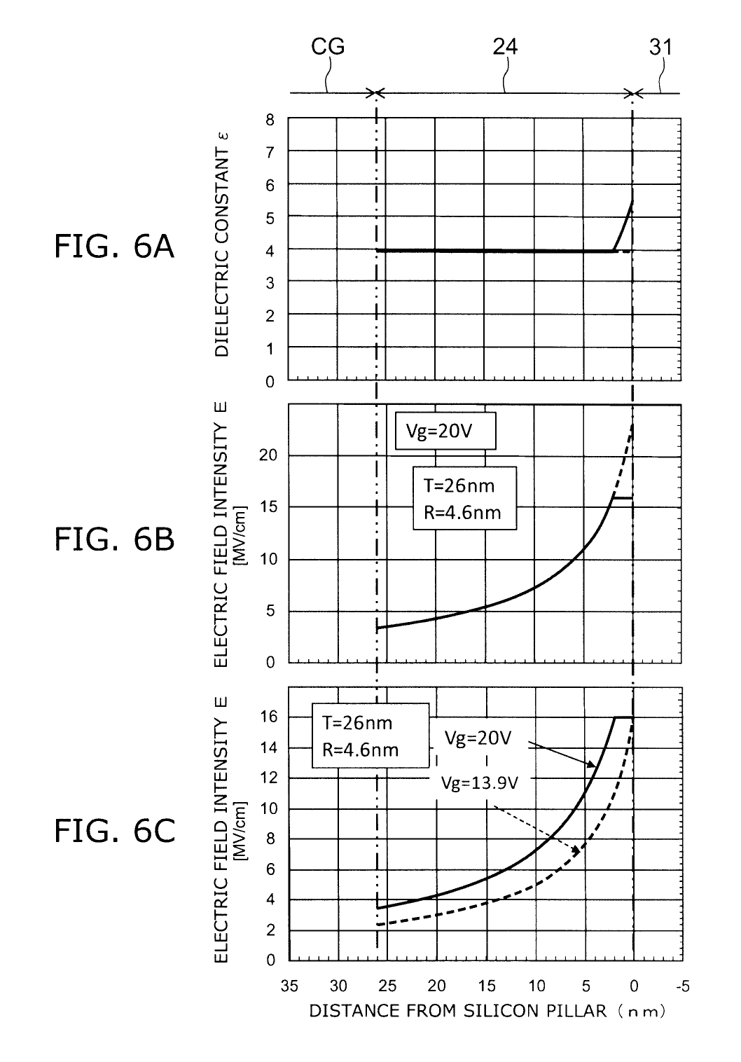

FIG. 6A is a graph illustrating the profile of the dielectric constant, where the horizontal axis represents the distance from the silicon pillar, and the vertical axis represents the dielectric constant. FIG. 6B is a graph illustrating the profile of the electric field intensity for a voltage of 20 V, where the horizontal axis represents the distance from the silicon pillar, and the vertical axis represents the electric field intensity. FIG. 6C is a graph illustrating the profile of the electric field intensity for a maximum electric field of 16 MV/cm, where the horizontal axis represents the distance from the silicon pillar, and the vertical axis represents the electric field intensity.

In this practical example, the electric field intensity E in the memory film 24 was calculated by assuming the dielectric constant ∈ in the memory film 24. Here, to simplify calculation, the memory film 24 was assumed to be a single-layer silicon oxide film. That is, the dielectric constant of the charge storage layer 26 and the block layer 25 was assumed to be equal to the dielectric constant of the tunnel layer 27. Furthermore, the radius R (see FIG. 3) of the silicon pillar 31 was set to 4.6 nm, and the film thickness T (see FIG. 3) of the memory film 24 was set to 26 nm. In FIGS. 6A to 6C, the solid line shows this practical example, and the dashed line shows a comparative example.

As shown by the dashed line in FIGS. 6A and 6B, if the dielectric constant is fixed in the memory film 24, the electric field intensity E in the memory film 24 was increased toward the silicon pillar 31, and maximized at the interface with the silicon pillar 31. In contrast, as shown by the solid line in FIGS. 6A and 6B, in this practical example, in the portion of the memory film 24 corresponding to the tunnel layer 27, i.e., in the portion within 2 nm from the silicon pillar 31, the dielectric constant is monotonically increased toward the silicon pillar 31.

Thus, in the direction from the inner surface of the through hole 21 to the center of the through hole, the electric field intensity E was increased in the portion of the memory film 24 corresponding to the block layer 25 and the charge storage layer 26, but nearly fixed in the portion corresponding to the tunnel layer 27. Thus, the electric field concentration was relaxed.

Furthermore, as shown in FIG. 6C, the maximum of the electric field intensity E was set to 16 MV/cm, which is the breakdown voltage of silicon oxide. In this case, in the comparative example, the maximum voltage applicable was 13.9 V. In contrast, in this practical example, the overall electric field intensity can be increased by the amount of relaxing the electric field concentration in the tunnel layer 27. Thus, the maximum voltage applicable was 20 V.

The embodiment described above can realize a semiconductor memory device with high operating speed.

While certain embodiment has been described, this embodiment has been presented by way of example only, and is not intended to limit the scope of the inventions. Indeed, the novel embodiment described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor memory device comprising:
a multilayer body with a plurality of insulating films and electrode films alternately stacked, the multilayer body including a through hole extending in stacking direction of the insulating films and the electrode films;
a block layer provided on an inner surface of the through hole;
a charge storage layer surrounded by the block layer;
a tunnel layer surrounded by the charge storage layer; and
a semiconductor pillar surrounded by the tunnel layer,
dielectric constant of a portion of the tunnel layer on a side of the semiconductor pillar being higher than dielectric constant of a portion of the tunnel layer on a side of the charge storage layer.

2. The device according to claim 1, wherein the dielectric constant of the tunnel layer monotonically increases in a direction from the inner surface of the through hole to central axis of the through hole.

3. The device according to claim 2, wherein the dielectric constant of the tunnel layer is inversely proportional to distance from the central axis of the through hole.

4. The device according to claim 1, wherein in a direction from the inner surface of the through hole to central axis of the through hole, the dielectric constant of the tunnel layer is fixed in an outer portion of the tunnel layer, and monotonically increases in an inner portion of the tunnel layer.

5. The device according to claim 1, wherein as viewed in the stacking direction of the insulating films and the electrode films, the through hole has a circular shape, and the semiconductor pillar also has a circular shape.

6. The device according to claim 1, wherein
the tunnel layer is made of a material containing silicon, oxygen, and nitrogen, and
nitrogen concentration in the portion of the tunnel layer on the side of the semiconductor pillar is higher than nitrogen concentration in the portion of the tunnel layer on the side of the charge storage layer.

7. The device according to claim 6, wherein the dielectric constant of the tunnel layer monotonically increases in a direction from the inner surface of the through hole to central axis of the through hole.

8. The device according to claim 7, wherein the dielectric constant of the tunnel layer is inversely proportional to distance from the central axis of the through hole.

9. The device according to claim 6, wherein in a direction from the inner surface of the through hole to central axis of the through hole, the dielectric constant of the tunnel layer is fixed in an outer portion of the tunnel layer, and monotonically increases in an inner portion of the tunnel layer.

10. The device according to claim 6, wherein as viewed in the stacking direction of the insulating films and the electrode films, the through hole has a circular shape, and the semiconductor pillar also has a circular shape.
